(19) United States
(12) Patent Application Publication
(10) Pub. No.: US 2019/0027943 A1
(43) Pub. Date: Jan. 24, 2019

(54) Micro-Battery Array

(71) Applicant: Leigh M. Rothschild, Miami, FL (US)

(72) Inventor: Leigh M. Rothschild, Miami, FL (US)

(21) Appl. No.: 16/043,316

(22) Filed: Jul. 24, 2018

Related U.S. Application Data
(60) Provisional application No. 62/535,993, filed on Jul. 24, 2017.

(51) Int. Cl. H02J 7/00; G01R 31/36

(52) U.S. Cl. CPC H02J 7/0026; G01R 31/3655; H02J 7/0024; G01R 31/3624

(57) ABSTRACT

A micro-battery array is disclosed. The micro-battery array is present in a battery unit. The battery unit comprises a rectifier for conditioning current and voltage supplied to the battery unit. The battery unit further comprises a plurality of micro-batteries connected in parallel. Each micro-battery of the plurality of micro-batteries may be charged simultaneously while the battery unit is charged. The battery unit may further comprise a controller connected to the battery unit. The controller may monitor charge levels of each micro-battery and may switch usage of micro-batteries in the battery unit based on the charge levels. A next micro-battery in the battery unit may be used while charge of a currently used micro-battery goes below a threshold value.

### PRIORITY

This patent application claims the benefit of U.S. Provisional Application No. 62/535,993, filed on Jul. 24, 2017.

### FIELD OF THE DISCLOSURE

The present disclosure is generally related to a battery for powering user devices, and more particularly related to a battery having cells connected in parallel.

### BACKGROUND

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may also correspond to implementations of the claimed technology.

A battery acts as a power source for portable user devices like smart phones, tablets, and laptops. A size of the battery may be big or small to power the device for a defined number of hours. The battery may be one of a Nickel-Cadmium battery, Lead Acid battery, and a Lithium ion battery. The battery is generally selected for a user device based on the current and voltage requirements, running time required for the device, charge-discharge cycles supported, operating temperature, load impedance, and physical configuration of the battery such as size and weight.

Lead Acid batteries have found myriad uses in Uninterrupted Power Supply (UPS), electric vehicles, automobiles, forklifts, and emergency lights for their high charge density and large battery life. But, the Lead Acid batteries are associated with several disadvantages, such as inability to store in discharged conditions, poor weight-to-energy density limits, and thermal runaway in improper charging conditions.

For example, Lithium ion batteries are used in majority of portable electronic devices, such as mobile phones, laptops, and digital cameras. Lithium ion batteries found their diverse use due to their light weight, availability in different size and shapes, and lack of memory effect. But, the Lithium ion batteries have many associated disadvantages, such as reduced charge flow due to over the time deposition of chemicals inside an electrolyte of the battery, capacity loss of the battery by high charging and high temperatures, and short circuiting of battery's terminals by deep discharging.

Further, super capacitors provide a quick charging time. But, on the other hand the super capacitors also suffers from several disadvantages, such as quick discharge time, very low charge capacity, and small working life.

Despite availability of various types of batteries, there remains a common limitation associated with all types of the batteries i.e. the charging time. The batteries require a lot of charging time to reach high or complete charging levels. There exists a few techniques like super charging and over voltage charging for quickly charging the batteries for an optimum charge level, but none could quickly charge the batteries completely within a fraction of time. Thus, there remains a need of a system for improving the charging time of a battery.

### BRIEF DESCRIPTION OF THE DRAWINGS

The accompanying drawings illustrate various embodiments of systems, methods, and embodiments of various other aspects of the disclosure. Any person with ordinary skills in the art will appreciate that the illustrated element boundaries (e.g. boxes, groups of boxes, or other shapes) in the FIGURES represent one example of the boundaries. It may be that in some examples one element may be designed as multiple elements or that multiple elements may be designed as one element. In some examples, an element shown as an internal component of one element may be implemented as an external component in another, and vice versa. Furthermore, elements may not be drawn to scale. Non-limiting and non-exhaustive descriptions are described with reference to the following drawings. The components in the figures are not necessarily to scale, emphasis instead being placed upon illustrating principles.

FIG. 1 illustrates a block diagram of a micro-battery array 100, according to an embodiment.

### DETAILED DESCRIPTION

Some embodiments of this disclosure, illustrating all its features, will now be discussed in detail. The words “comprising,” “having,” “containing,” and “including,” and other forms thereof, are intended to be equivalent in meaning and be open ended in that an item or items following any one of these words is not meant to be an exhaustive listing of such item or items, or meant to be limited to only the listed item or items.

It must also be noted that as used herein and in the appended claims, the singular forms “a,” “an,” and “the” include plural references unless the context clearly dictates otherwise. Although any systems and methods similar or equivalent to those described herein can be used in the practice or testing of embodiments of the present disclosure, the preferred, systems and methods are now described.

Embodiments of the present disclosure will be described more fully hereinafter with reference to the accompanying drawings in which like numerals represent like elements throughout the several FIGURES, and in which example embodiments are shown. Embodiments of the claims may, however, be embodied in many different forms and should not be construed as limited to the embodiments set forth herein. The examples set forth herein are non-limiting examples and are merely examples among other possible examples.

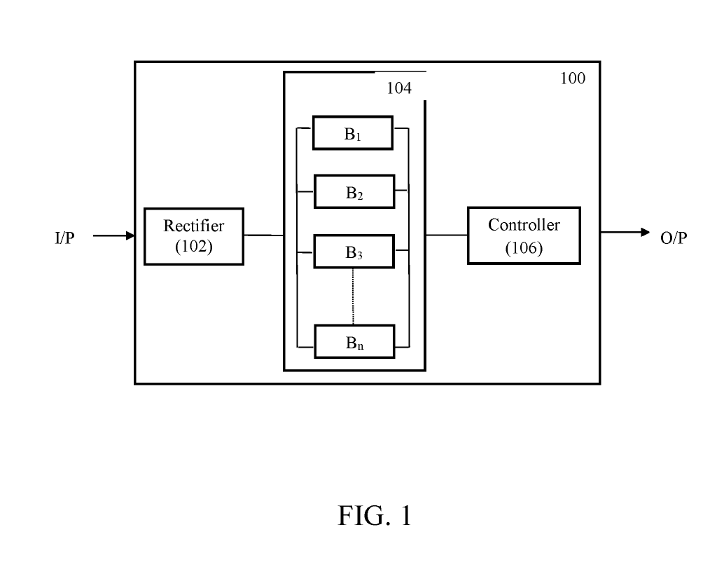

FIG. 1 illustrates a block diagram of a micro-battery array 100. The micro-battery array 100 may comprise a rectifier 102 for conditioning current and voltage supplied to the battery unit. In one embodiment, the rectifier may be used for stepping down of supplied voltage and thereby converting an alternating current to a direct current. The rectifier 102 may comprise known current and voltage conditioning elements such as a transformer, rectifying diodes, and voltage regulating Integrated Circuits.

In one embodiment, voltage regulating Integrating Circuits of 78xx and 79xx series may be used. For example, 7805 I.C. may be used for providing a regulated output of +5 Volts, and 7905 I.C. may be used for providing a regulated output of −5 Volts. Similarly, different voltage regulating Integrating Circuits may be used for generating different voltage levels, as required in the circuitry.

In one embodiment, current limiting diodes may also be used to limit the current flow. Different diodes such as Zener diode and Schottky diode may be used as per requirement in the circuitry. Further, Micro-Electro-Mechanical systems may be used in place of components such as transformers and relays. Usage of such Micro-Electro-Mechanical systems helps in reducing size of the circuitry associated with a battery unit 104.

The rectifier 102 may be connected to the battery unit 104. The battery unit 104 may comprise a plurality of micro-batteries (B₁, B₂, B₃ . . . Bₙ). The plurality of micro-batteries may be connected in parallel. Thus, each micro-battery of the plurality of micro-batteries may charge simultaneously while the battery unit 104 is charged. In one case, each micro-battery of the plurality of micro-batteries may be of similar capacity.

The battery unit 104 may be connected with a controller 106. The controller 106 may monitor charge levels of each micro-battery of the battery unit 104. Further, the controller 106 may switch usage of micro-batteries present in the battery unit 104, based on the charge levels. A next micro-battery in the battery unit 104 may be used while charge of a currently used micro-battery goes below a threshold value.

In one embodiment, the micro-battery B₁ may be used currently by a device. The controller 106 may determine charge of micro-battery B₁ to be depleted or fallen below a defined threshold value. The controller 106 may successively switch to the next micro-battery i.e. micro-battery B₂. The controller 106 may use the micro-battery B₂ till charge of the micro-battery B₂ gets depleted or falls below the defined threshold value and may similarly switch to usage of next micro-battery B₃ later.

In one embodiment, the controller 106 may comprise several algorithms for managing charging and discharging of each micro-battery. At least one of the several algorithms, executed by the controller 106, may identify charge of one micro-battery to be depleted or fallen below the defined threshold value. In such case, the at least one algorithm may identify another micro-battery, amongst the plurality of micro-batteries, having a sufficient charge, and may start utilizing the identified micro-battery. The controller 106 may use the micro-battery till its charge depletes or falls below the defined threshold value and may similarly switch to usage of yet another micro-battery, identified to comprise sufficient charge, by the at least one algorithm.

In one embodiment, the controller 106 may select an algorithm for charging the micro-batteries, based on a user's input. The user may select different charging rates, such as 0.1 C and 0.5 C for slow charging of the micro-batteries. The user may select a charging rate equal to or greater than 1 C for fast charging of the micro-batteries. Further, the controller 106 may use suitable algorithms during a slow charging mode and a fast charging mode. The algorithms may maintain different timers for disconnecting the micro-batteries from a power supply, to prevent overcharging of the micro-batteries. Further, the algorithms may also monitor temperatures of the micro-batteries for preventing the overcharging. In one case, the algorithm may maintain a timer of 10 minutes for disconnecting the micro-batteries from the power supply, while a 0.1 C charging rate is selected. In another case, the algorithm may maintain a timer of 1 minute for disconnecting the micro-batteries from the power supply, while a 2.5 C charging rate is selected.

In one embodiment, an algorithm may be used to identify a faulty micro-battery amongst the plurality of micro-batteries. In one case, the algorithm may identify the faulty micro-battery based on charging characteristics of the micro-battery. The charging characteristics may depend on at least one factor selected from charging time, discharge time, current output, voltage output, least charge level, and maximum charge level.

In one embodiment, the user may be alerted about any faulty micro-battery, identified by an algorithm, based on the charging characteristics of the micro-battery. The user may be alerted by providing an error code or message through a buzzer, Light Emitting Diode (LED), and Liquid Crystal Display (LCD). Such identification of the faulty micro-battery may help the user to replace the micro-battery in-time.

In one embodiment, the battery unit 104 may further comprise at least one micro-battery configured for usage during an emergency mode operation of a device utilizing the battery unit 104 as a power source. In one case, a smart phone or other device may utilize the battery unit 104 as the power source and the micro-battery Bₙ may be configured for usage during the emergency mode operation. The emergency mode operation may refer to making a call or data usage while charge of all the micro-batteries B₁−Bₙ₋₁, except Bₙ, has depleted.

In one embodiment, the user may define a number of micro-batteries to be kept reserved for the emergency mode operation. The controller 106 may disconnect such micro-batteries to prevent them from discharging, until the emergency mode operation is activated. Activation of the emergency mode operation by the user may trigger the controller 106 to activate the reserved micro-batteries and successively making them available for use.

It is well understood from the above disclosure that the described micro-battery array could be used in any user device such as a smart phone, tablet, laptop, i-pod, and mp3 players. Further, the above described micro-battery array could result in faster charging times of battery due to parallel charging of the micro-batteries present in the micro-battery array.

What is claimed is:

1. A micro-battery array comprising:
a battery unit comprising a plurality of micro-batteries connected in parallel, wherein each micro-battery of the plurality of micro-batteries is charged simultaneously while the battery unit is charged; and
a controller connected to the battery unit for monitoring charge levels of each micro-battery and switching usage of micro-batteries in the battery unit based on the charge levels, wherein a next micro-battery in the battery unit is used while charge of a currently used micro-battery goes below a threshold value.

2. The micro-battery array of claim 1, further comprising a rectifier for conditioning current and voltage supplied to the battery unit.

3. The micro-battery array of claim 1, further comprising at least one micro-battery configured for usage during emergency mode operation of a device.

4. The micro-battery array of claim 1, wherein each micro-battery of the plurality of micro-batteries is of similar capacity.

5. The micro-battery array of claim 1, further comprising utilizing an algorithm for monitoring charge of each micro-battery.

6. The micro-battery array of claim 1, further comprising utilizing an algorithm for identifying the next micro-battery in the battery unit for usage.

7. The micro-battery array of claim 1, further comprising utilizing an algorithm for identifying a faulty micro-battery amongst the plurality of micro-batteries.

8. The micro-battery array of claim 1, wherein the controller selects an algorithm amongst a plurality of algorithms for managing charging of the plurality of micro-batteries, wherein the algorithm is selected based on a charging rate.

9. The micro-battery array of claim 1, further comprising utilizing the micro-battery array as a power source in a smart phone.

10. A method of operating a micro-battery array, comprising:
utilizing a battery unit comprising a plurality of micro-batteries connected in parallel, wherein each micro-battery of the plurality of micro-batteries is charged simultaneously while the battery unit is charged; and
utilizing a controller connected to the battery unit for monitoring charge levels of each micro-battery and switching usage of micro-batteries in the battery unit based on the charge levels, wherein a next micro-battery in the battery unit is used while charge of a currently used micro-battery goes below a threshold value.

11. The method of claim 10, further comprising providing a rectifier for conditioning current and voltage supplied to the battery unit.

12. The method of claim 10, further comprising configuring at least one micro-battery for usage during emergency mode operation of a device.

13. The method of claim 10, wherein each micro-battery of the plurality of micro-batteries is of similar capacity.

14. The method of claim 10, further comprising monitoring charge of each micro-battery, by utilizing an algorithm.

15. The method of claim 10, further comprising identifying the next micro-battery in the battery unit for usage, by utilizing an algorithm.

16. The method of claim 10, further comprising identifying a faulty micro-battery amongst the plurality of micro-batteries, by utilizing an algorithm.

17. The method of claim 10, further comprising selecting an algorithm amongst a plurality of algorithms for managing charging of the plurality of micro-batteries, wherein the algorithm is selected based on a charging rate.

18. The method of claim 10, further comprising utilizing the micro-battery array as a power source in a smart phone.
